(19) United States
(12) Patent Application Publication
(10) Pub. No.: US 2024/0186139 A1
(43) Pub. Date: Jun. 6, 2024

(54) SUBSTRATE PROCESSING METHOD

(71) Applicant: ASM IP Holding B.V., Almere (NL)

(72) Inventors: Sungdae Woo, Hwaseong-si (KR); Kwangman Ko, Uiwang-si (KR); SungBae Kim, Yongin-si (KR); JuSeok Jeon, Yangju-si (KR)

(21) Appl. No.: 18/524,307

(22) Filed: Nov. 30, 2023

Related U.S. Application Data
(60) Provisional application No. 63/430,088, filed on Dec. 5, 2022.

(51) Int. Cl. H01L 21/02; C23C 16/24; C23C 16/26; C23C 16/34; C23C 16/505; C23C 16/56; H01J 37/32

(52) U.S. Cl. CPC H01L 21/0234; C23C 16/24; C23C 16/26; C23C 16/34; C23C 16/505; C23C 16/56; H01J 37/32449; H01L 21/02186; H01L 21/02274; H01L 21/0228; H01J 37/32082; H01J 2237/332

(57) ABSTRACT

Provided is a method of forming a TiN spacer film on the patterned structure comprising a step of loading a substrate onto a chamber, a step of forming a film on the substrate; a step of post treatment to the film; and a step of unloading the substrate, wherein the step of forming the film on the substrate comprises supplying a first gas and a second gas sequentially and alternately, wherein the step of post treating to the film comprises supplying treatment gas to the substrate, wherein the second gas and the treatment gas are activated by RF power.

### CROSS-REFERENCE TO RELATED APPLICATIONS

This application claims priority to U.S. Provisional Patent Application Ser. No. 63/430,088 filed Dec. 5, 2022 and titled SUBSTRATE PROCESSING METHOD, the disclosure of which is hereby incorporated by reference in its entirety.

### FIELD OF INVENTION

The disclosure relates to a method for forming a spacer film in a double patterning process, and more specifically to a method for forming a spacer film with uniform film compositions and without being bent in a patterning structure due to a narrow width.

### BACKGROUND OF THE DISCLOSURE

In patterning process for manufacturing a semiconductor device, a spacer film is formed on a patterned structure such as hardmask film, followed by etching a portion of the spacer film. After etching and removing a portion of the spacer film, the spacer film remains in a regular interval. After that, the patterned structure such as hardmask film between the spacer films is selectively etched out and removed. Conventionally, the spacer film comprises SiO₂ and the SiO₂ spacer film is formed by plasma enhanced atomic film deposition (PEALD) at low temperature.

FIG. 1 illustrates a conventional method of forming a spacer film on a patterned structure and patterning process using the method. Each step of FIG. 1 is described as follows.

A step of forming a patterned structure (FIG. 1A): a first film 110 is formed on a substrate 100 and a second film 120 is formed on the first film 110. The first film 110 may be an insulating film (such as SiN, amorphous carbon, or amorphous silicon) and is removed in the subsequent etching process. The second film 120 may comprise a polymeric film such as spin-on-hardmask (SOH) film and carbon spin-on-hardmask (C-SOH) film and is easily removed by wet etching, ashing, or strip process.

A step of forming a film on the patterned structure (FIG. 1 B): a third film 130 is formed on the second film 120. The third film 130 may be formed by an atomic film deposition (ALD) method or a plasma atomic film deposition (PEALD) method to form a conformal film on the second film 120. The third film 130 may comprise a SiO₂ film.

A step of forming a spacer film (FIG. 1 C): An anisotropic etching is performed on the third film 130 disposed on the second film 120. The etching process may be a wet etching or a dry etching process. For instance, an etch-back process may be carried out by dry etching, such as reactive ion etching (RIE), resulting in removal of an upper portion of the third film 130. Therefore, a spacer film 140 may be formed on the side wall of the second film. That is, the spacer film 140 may be a part of the third film 130, and more specifically, may be the third film 130 formed on the side wall of the second film 120. After the spacer film 140 is formed, a width a of spacer film 140, a width b of the second film 120, and a width c between spacers may be the same (a=b=c).

A step of removing the second film (FIG. 1 D): The second film 120 between the spacer films 140 is removed. The second film 120 may be removed by a wet etching, ashing, or strip process.

A step of removing the first film (FIG. 1 E): The first film 110 is removed. The spacer film 140 acts as a mask film and the first film 110 under the mask film remains. However, an exposed portion of the first film 110 not under the mask film is removed. This step is carried out by a wet etching process.

A step of removing the mask film (FIG. 1 E): the mask film is removed. As previously described, the mask film may the third film 130 formed on the second film 120, that is, the spacer film 140. The mask film in this step may be removed by an ashing or strip process.

A step of completing forming a patterned structure in the first film (FIG. 1 F): After the mask film is removed, a patterned structure in the first film 110 is formed and the widths between the patterned structures may be uniform (a=b=c). The number of patterned structures in FIG. 1 F may be doubled compared to the number of patterned structures in FIG. 1A. This process is referred to as a Spacer Defined Double Patterning (SDDP) using spacer films and usually used for forming a micro circuit on the substrate.

Meanwhile, as the line width of the semiconductor circuit is reduced, the thickness of SiO₂ spacer film formed on the patterned structure may also be reduced. However, the thin SiO₂ spacer film with reduced thickness may have reduced mechanical strength, resulting in bending of the SiO₂ spacer film and lower yield of the semiconductor device.

FIG. 2 illustrates some examples of leaning or bending of the SiO₂ spacer film after the patterned structure located between the SiO₂ spacer films is removed.

FIG. 2 corresponds to FIG. 1 D and FIG. 1 F respectively. In FIG. 2, the spacer film 140 may lean to one side. Therefore, in subsequent processes, the width between the patterned structures may not be uniform (a≠a′≠a″≠a′″≠b≠b′≠c).

Therefore, a TiN film may be used as a spacer film instead of conventional SiO₂ film in order to form a micro circuit. The elastic modulus of TiN film may be above 150 GPa, higher than the elastic modulus of SiO₂ film of 100 GPa. As the mechanical strength of TiN film is higher than the conventional SiO₂ film, the TiN film does not lean even though the thickness of TiN film is reduced.

The TiN spacer film may be formed uniformly on the patterning structure by PEALD. However, as the line width of the semiconductor circuit is reduced, the quality of TiN film (e.g. film composition) may not be uniform depending on the position of the patterned structure on which the TiN film is formed. That is referred to as CD effect (Critical Dimension effect).

FIG. 3A and FIG. 3 B illustrate non-uniform film quality of TiN film over the surface of the patterned structure when the TiN film is formed as a spacer film thereon (CD effect).

In FIG. 3A, a plasma density in the patterned structure region may be different depending on a width w of the patterned structure. In FIG. 3A, large amounts of active species (e.g. activated reactant) reach an upper portion R1 of the patterned structure, and the kinetic energy of the active species and the plasma density may be high therein. In contrast, the amounts of active species reaching an lower portion R2 of the patterned structure may relatively small and the kinetic energy of active species and the plasma density may be low. In other words, the distribution of active species and the plasma density in the patterned structure may be determined by the width w of the patterned structure, and the quality of a TiN film 130 formed on the surface of the patterned structure may be different depending on the position of the surface in the patterned structure on which the TiN film 130 may be formed.

For instance, when the TiN film is formed on a patterned structure 120 as a spacer film, a stoichiometric TiN film may be formed in the upper portion R1 of the patterned structure, whereas in the lower portion R2 of the patterned structure a non-stoichiometric TiN film may be formed due to incomplete chemical reaction between a source gas and a reactant. This may result in non-uniform wet etch rate along the surface from the top to the bottom of the patterned structure.

In addition, when the TiN film is formed on the patterned structure of the substrate and the substrate is unloaded and transferred from the chamber to carry out an etching process, the TiN film formed in the lower portion of the patterned structure may react with outside gas such as oxygen. A portion of TiN film therein may be converted into TiON and/or TiO₂ film.

FIG. 3 B illustrates a width between spacer films 130 being not uniform (w1≠w2) along the depth of the patterned structure due to non-uniform film quality. This occurs after a certain thickness of spacer films 130 is formed, followed by an etch back process resulting in an etching out the patterned structures 120.

In FIG. 3 B, the spacer film 130 in the lower portion of the patterned structure is etched out more than in the upper portion. As previously described, a portion of TiN film in the lower portion is non-stoichiometric and converted into TiON and/or TiO₂ film of which chemical bonding strength is weaker than the chemical bonding strength of TiN film. Therefore, more spacer films therein may be removed together when the patterned structures 120 are removed. This phenomenon (CD effect) especially increases when the width between the patterned structures is less than 40 nm.

FIG. 4A shows a high-resolution TEM (Transmission Electron Microscope) image of TiN film formed on the patterned structure with the width of 70 nm and 35 nm and the depth of 90 nm.

FIG. 4 B shows an EDS (Energy Dispersive Spectrometer) analysis image of TiN film showing an oxygen element distribution therein. As shown in FIG. 4 B, in a patterned structure with the width of 35 nm, oxygen elements may be distributed in the lower portion of the patterned structure, forming and a TiO₂ film and a TiON film. Whereas in a patterned structure with the width of 70 nm, a TiN film may still be maintained in the lower portion of the patterned structure.

FIG. 4 C shows an image of TiN film remaining on the patterned structure with the width of 35 nm after the film is wet-etched in 100:1 dHF (diluted hydrofluoric acid) etching solution. As shown in FIG. 4 C, the TiN film is still maintained in the upper portion of the patterned structure, whereas the TiN film in the lower portion thereof is significantly removed. That indicates the TiN film in the lower portion of the patterned structure reacted with an oxygen and converted into an oxide film with weak bonding structure (e.g. TiO₂).

Therefore, the disclosure describes a substrate processing method for forming a TiN spacer film with a uniform film quality along the surface of the patterned structure regardless of the position on which the film is formed.

### SUMMARY OF THE DISCLOSURE

In one or more embodiments, a method for forming a TiN spacer film in double patterning process is provided. In more detail, a method for forming a TiN spacer film with uniform film compositions and without being bended on a patterned structure with narrow width is provided.

In one or more embodiments, a method for forming a spacer film comprises a step of forming a film on a substrate, followed by a step of post treatment step, wherein the step of forming a film on a substrate comprises a supplying a first gas and a second gas sequentially and alternately, and the step of post treatment comprises supplying treatment gases, wherein the first gas comprises a titanium, the second gas comprises a nitrogen, wherein the second gas and the treatment gases are activated by RF power.

In one or more embodiments, the treatment gases comprise a second gas and a third gas, wherein the third gas comprises a hydrogen.

In one or more embodiments, the first gas comprises at least one of tetrakis(dimethylamino) titanium(IV), titanium isopropoxide, titanium tetrachloride, or a mixture thereof, the second gas comprises at least one of N₂, NH₃, N₂H₂, N₂H₄, or a mixture thereof and the third gas removes carbons from the film.

In one or more embodiments, the flow rate of the second gas is greater than the flow rate of the third gas during the step of forming the film on the substrate.

In one or more embodiments, the flow rate of the third gas is greater than the flow rate of the second gas during the post treatment to the film.

In one or more embodiments, the intensity of RF power applied to the second gas during the step of forming the film is greater than the intensity of RF power applied to the treatment gases during the step of post treatment.

In one or more embodiments, the frequency of RF power applied to the second gas during the step of forming the film is the same or greater than the frequency of RF power applied to the treatment gases during the step of post treatment.

In one or more embodiments, the step of forming a film and the step of post treatment to the substrate are repeated cyclically a plurality of times, wherein the cycle ratio of the step of forming a film to the step of post treatment to the film is 10:1.

In one or more embodiments, a width between the patterned structures is less than 40 nm.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIG. 1 illustrates a method of forming a spacer film on a patterned structure and patterning process using the method.

FIG. 2 illustrates some examples of leaning of SiO₂ spacer film after the patterned structure located between SiO₂ spacer films is removed.

FIG. 3: A and B illustrate non-uniform film quality of TiN film over the surface of the patterned structure when TiN film is formed as a spacer film thereon (CD effect).

FIG. 4: A shows a high-resolution TEM image of TiN film formed on the patterned structure with the width of 70 nm and 35 nm and the depth of 90 nm; B shows an EDS image of TiN film showing an oxygen element distribution in the TiN film; C shows an image of TiN film formed on the patterned structure with the depth of 35 nm after the film is wet-etched in 100:1 dHF (diluted hydrofluoric acid) etching solution.

FIG. 5 shows a process flow chart showing a substrate processing method according to an embodiment of the disclosure.

FIG. 6 illustrates a timing graph for processing a substrate according to an embodiment of FIG. 5.

FIG. 7 illustrates a reaction mechanism occurring in TiN film when an activated hydrogen and a nitrogen are suppled as a post treatment gas.

FIG. 8: A shows an image of TEM-EDS analysis on oxygen element distribution in the lower portion of the patterned structure with the width of 35 nm when no post treatment step is applied; B shows an image of TEM-EDS analysis on oxygen element distribution in the lower portion of the patterned structure with the width of 35 nm when a post treatment step is applied.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

The illustrations presented herein are not meant to be actual views of any particular material, structure, or device, but are merely idealized representations that are used to describe embodiments of the disclosure.

The particular implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various figures are intended to represent exemplary functional relationships and/or physical couplings between the various elements. Many alternative or additional functional relationship or physical connections may be present in the practical system, and/or may be absent in some embodiments.

First, according to one or more embodiments of the present disclosure, a substrate processing method in which a TiN spacer film is formed on a substrate will be described below.

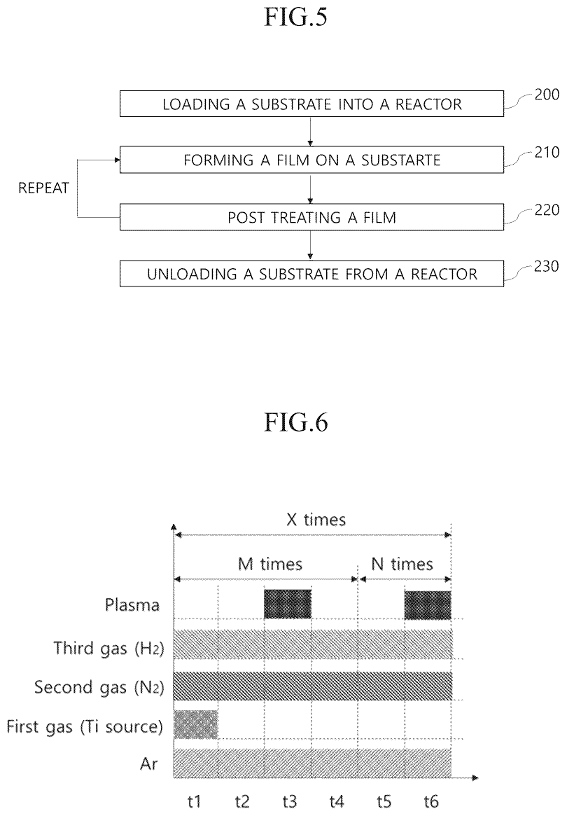

FIG. 5 shows a process flow chart showing a substrate processing method according to an embodiment of the disclosure.

Each step of FIG. 5 is described in detail as follows.

First step 200: A step of loading a substrate onto a chamber. The substrate may be loaded into a chamber. The substrate may have a patterned structure such as a gap. The chamber may comprise a gas supply unit and a substrate support unit, and at least one of them may be connected to a RF power generating unit. The substrate support unit may further comprise a heating block and a susceptor mounted thereon. The heating block may heat up the substrate mounted on the susceptor to a set temperature. The chamber may comprise a plurality of reactors and a plurality of substrate may be loaded onto the reactors.

Second step 210: A step of forming a film on the substrate. In the second step 210, a source gas as a first gas and a reactant as a second gas may be supplied sequentially and alternately to the substrate and form a film on the patterned structure. The source gas may comprise a titanium-containing gas and the reactant may comprise a nitrogen-containing gas. The titanium-containing gas may comprise at least one of tetrakis(dimethylamino) titanium(IV), titanium isopropoxide, titanium tetrachloride, or a mixture thereof, and the nitrogen-containing gas may comprise at least one of N₂, NH₃, N₂H₂, N₂H₄, or a mixture thereof. The reactant may be activated by RF power and react chemically with the source gas, and a TiN film may be formed on the patterned structure of the substrate accordingly).

The second step 210 may be repeated a plurality of times (M times) and a TiN film is formed uniformly on the substrate. To activate more reactant, high frequency RF power may be applied. For instance, 10 MHz to 60 MHz RF power may be applied.

In another embodiment, a third gas may be further supplied in the second step 210. The third gas may comprise a hydrogen-containing gas, for instance, diatomic hydrogen. The hydrogen may be activated by RF power and react with a residual carbon in the TiN film to remove the residual carbon from the TiN film. To generate a larger amount of activated nitrogen, the flow rate of the nitrogen may be greater than the flow rate of hydrogen. For instance, the flow rate of nitrogen may be 500 sccm to 1,000 sccm, while the flow rate of hydrogen may be 30 sccm to 300 sccm.

Third step 220: A step of post treating a film. In the third step 220, a post treating the TiN film formed on the patterned structure may be carried out. The quality of TiN film (e.g. film composition) may become more uniform due to the post treatment. More specifically, the quality of TiN film formed in the lower portion of the patterned structure may be improved. In this step, the second gas and the third gas may be supplied as a treatment gas. The second gas used in the third step 220 may comprise a nitrogen-containing gas, the same as the second gas used in the second step 210, and it may comprise at least one of N₂, NH₃, N₂H₂, N₂H₄, or a mixture thereof. The third gas used in the third step 220 may comprise a hydrogen-containing gas, the same as the third gas used in the second step 210, and it may comprise diatomic hydrogen.

When the second gas and the third gas as a treatment gas are supplied, the second gas and the third gas may be activated by RF power and supplied to the substrate. The activated third gas may react with a residual carbon in TiN film formed in the lower portion of the patterned structure to remove the residual carbon from the TiN film. As previously described, the TiN film formed in the lower portion of the patterned structure may be non-stoichiometric and lack nitrogen. Therefore, the activated second gas in the third step may further supply nitrogen to the TiN film formed in the lower portion of the patterned structure, to result in the TiN film becoming stoichiometric.

In one or more embodiments, the intensity of RF power applied to the second gas during the step of forming the film may be greater than the intensity of RF power applied to the treatment gases during the step of post treatment.

In one or more embodiments, the frequency of RF power applied to the second gas during the step of forming the film is the same or greater than the frequency of RF power applied to the treatment gases during the step of post treatment. For instance, 10 MHz to 60 MHz RF power may be applied during the step of forming the film and during the step of post treatment. But in another embodiment, low frequency RF power may be applied to supply activated species (e.g. activated second gas and the third gas) to the lower portion of the patterned structure during the step of post treatment. For instance, 100 kHz to 600 kHz RF power may be applied, or at least one of high frequency RF power and low frequency RF power or both may be applied during the step of post treatment.

In the third step, the intensity of RF power applied in the third step may be lower than that applied in the second step to reduce a plasma damage to the TiN film formed in the second step. For instance, a RF power of 400 W to 1,000 W may be applied in the second step, while a RF power of 100 W to 500 W may be applied in the third step.

In the third step, RF power may be applied longer than in the second step to promote sufficient chemical reactions within the lower portion of the patterned structure. For instance, RF power may be applied for 1 second to 5 seconds in the second step, whereas RF power may be applied for 2 seconds to 8 seconds in the third step. Therefore, the reduction of concentration of active species due to low frequency RF power and/or low intensity RF power may be compensated.

In the third step, the amount of third gas (e.g. hydrogen) supplied may be greater than the amount of second gas (e.g. nitrogen) supplied to further facilitate removal of a residual carbon from the TiN film.

The third step may be repeated a plurality of times (N times), and the second step and the third step may be repeated at a certain ratio. For instance, the second step may be repeated 10 times and the third step may be repeated 1 time and a super cycle comprising the second step and the third step may be repeated a plurality of times at that ratio (i.e. 10:1).

Fourth step 230: After the second step and the third step are repeated at a certain ratio and a target thickness of TiN film is reached, the process ends and the substrate is unloaded.

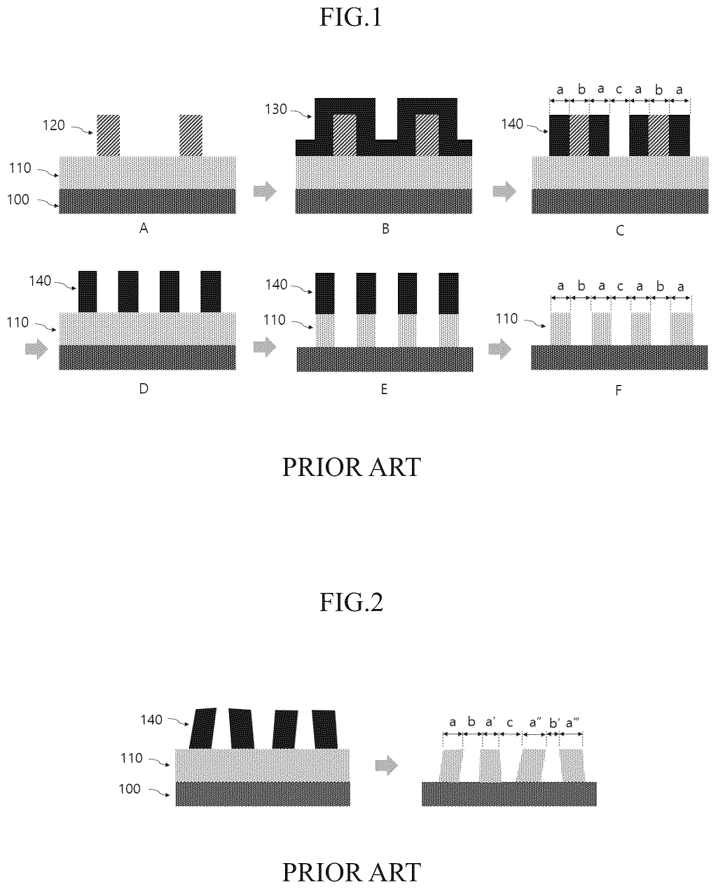

After a cycle from the first step 200 to the fourth step 230 is carried out, an etching process (e.g. reactive ion etching, wet etching and/or dry etching) may be carried out at the subsequent process step and a patterned structure may be formed as shown in FIG. 1 C to F.

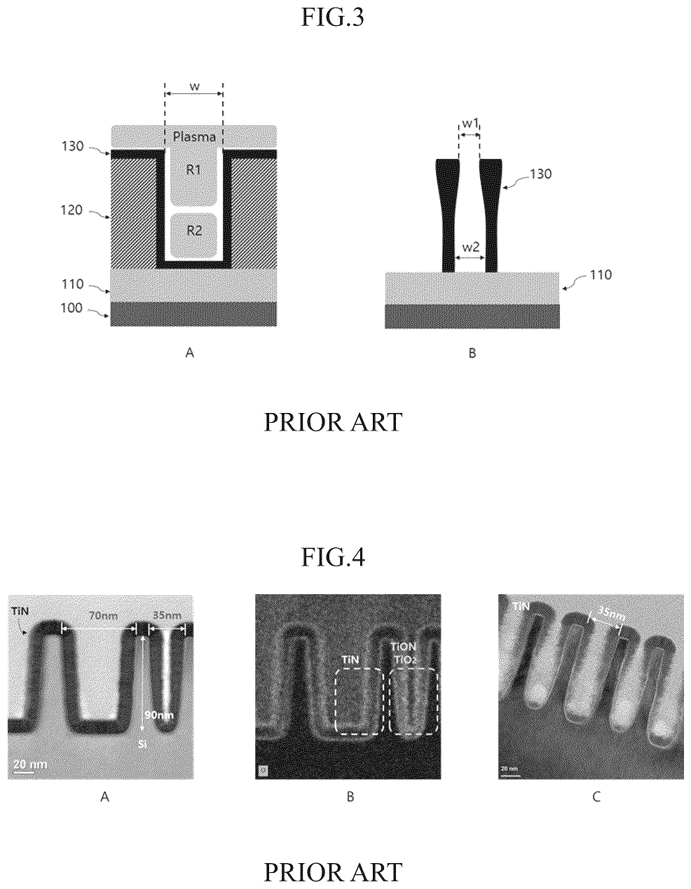

The subsequent process step may be carried out in another cluster system or in another chamber in the same cluster system. In case the subsequent process step is carried out in another cluster system, the substrate may be exposed to the outside atmosphere. But through the second step and the third step according to the disclosure, the quality of TiN film over the surface from the top to the bottom of the patterned structure may be improved, therefore, the TiN film formed in the lower portion of the patterned structure may not be removed at the subsequent process step and be remained. In an embodiment, the width of the upper portion and the width of the lower portion of the patterned structure may be the same. For instance, the widths of the upper portion and the lower portion of the patterned structure between TiN spacer films 130 in FIG. 3 B may be maintained constantly (w1=w2).

FIG. 6 illustrates a timing graph for processing a substrate according to an embodiment of FIG. 5.

The process from step t1 to the step t4 of FIG. 6 corresponds to the second step 210 of FIG. 5 and the process from the step t5 to the step t6 corresponds to the third step 220 of FIG. 5. The step t1 to t4 may be repeated M times and the step t5 to step t6 may be repeated N times. In addition, a super cycle comprising the step t1 to the step t4 and the step t5 to the step t6 may be repeated X times. In an embodiment of the disclosure, the cycle ratio of the step 1 to step 4 and the step 5 to step 6 (M:N) may be 10:1.

In another embodiment of FIG. 6, a RF power applied during the step t3 and the step t6 may be low frequency RF power. Under the low frequency RF power, the traveling distance of active species may be long such that the active species may reach to the lower portion of the patterned structure. Therefore, the quality of TiN film therein may be improved. Also, in FIG. 6, the intensity of RF power applied during the step t6 may be lower than the intensity of RF power applied during the step t3 to reduce a plasma damage to the TiN film. For instance, RF power of 700 W may be applied during the step t3, whereas RF power of 400 W may be applied during the step t6.

In the step t1 of FIG. 6, a source gas containing a titanium (Ti) as a first gas may be supplied. The source gas may be at least one of Tetrakis(dimethylamino) Titanium(IV), TDMAT; Titanium isopropoxide, TTIP; Titanium tetrachloride, TiCl₄, or a mixture thereof.

In the step t1 to the step t6 of FIG. 6, a reactant containing a nitrogen as a second gas may be supplied. The second gas may be at least one of: N₂, NH₃, N₂H₂, N₂H₄, or a mixture thereof.

In the step t1 to the step t6 of FIG. 6, a hydrogen-containing gas may be supplied as a third gas. The hydrogen-containing gas may be a hydrogen (H₂).

In the step t3 and the step t6 of FIG. 6, RF power supplied may be at least one of direct plasma and remote plasma or both.

In the step t1 to the step t6 of FIG. 6, Ar gas may be supplied as a source (first gas) carrier gas and/or a purge gas to purge the gas supply path and the chamber.

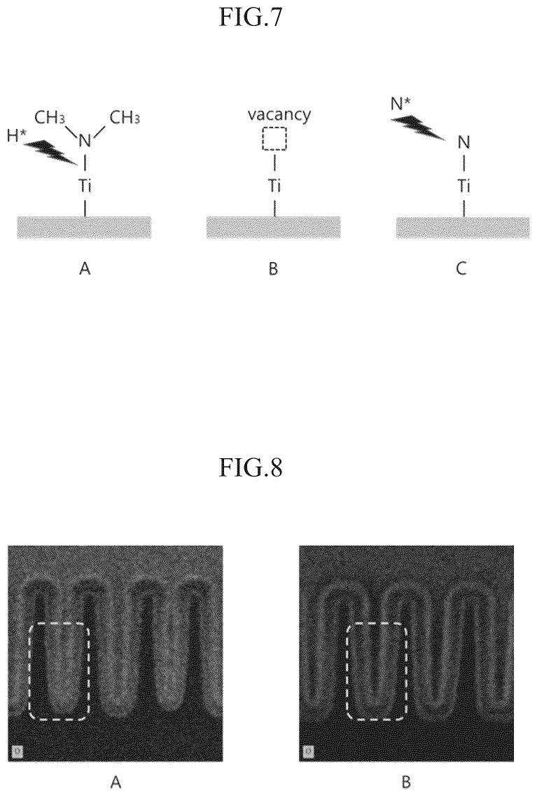

FIG. 7 illustrates a reaction mechanism occurring in TiN film when activated hydrogen and a nitrogen are suppled as a post-treatment gas.

In the step A of FIG. 7, a TiN film is formed by supplying a titanium source gas and a nitrogen reactant to the substrate by PEALD. After that, activated hydrogen may be supplied to remove a ligand (i.e. —N(CH₃)₂). In more detail, in the lower portion of the patterned structure, a titanium source gas and a nitrogen reactant may not sufficiently react with each other and the ligand group may still remain in TiN film. The ligand group may be physically removed by an ion-bombardment effect of activated Ar. Or the ligand group may be removed by the reaction between hydrogen ions and amine (—N—) group.

In FIG. 7 B, a vacancy may be generated in the position where an amine group previously occupied.

In FIG. 7 C, an activated nitrogen is supplied and fills the vacancy, resulting in forming a TiN film without ligands. The TiN film from which the ligands are removed may exhibit enhanced bonding strength.

As illustrated in FIG. 7A to C, in case a TiN film is incompletely formed in the lower portion of the patterned structure, the residual impurities such as carbon may be removed and the quality of the film and its uniformity may be improved by supplying a post-treatment gas.

FIG. 8A shows an image of TEM-EDS analysis on oxygen element distribution in the lower portion of the patterned structure with the width of 35 nm when no post treatment step is applied.

FIG. 8 B shows an image of TEM-EDS analysis on oxygen element distribution in the lower portion of the patterned structure with the width of 35 nm when a post treatment step is applied.

FIG. 8A shows oxygen elements are detected in the lower portion of the patterned structure when the post treatment step is not applied. In addition, the film profile in the lower portion of the patterned structure is not clear compared to the film profile in the upper portion of the patterned structure, showing that the film bonding structure is incomplete and oxygen impurities are included therein.

FIG. 8 B shows oxygen elements are not detected in the lower portion of the patterned structure when the post treatment step is applied. In addition, the film profile from the upper portion to the lower portion of the patterned structure is clear and uniform, showing that the quality of the film from the upper portion to the lower portion of the patterned structure is uniform even though the width is less than 40 nm. Therefore, the disclosure has a technical advantage of enabling a film having a uniform film composition to be formed from the upper portion to the lower portion of the patterned structure even when the width of the pattern is very narrow, for instance, less than 40 nm.

Table 1 is test conditions of an embodiment of the disclosure.

TABLE 1
Test conditions of an embodiment

| | | Film | Post |
|---|---|---|---|
| Process condition | | forming step | treatment step |
| Process time | Source | 0.2 to 1.0 | |
| (second/cycle) | feeding step | (preferably | |
| | | 0.4 to 0.8) | |
| | Source | 0.2 to 1.0 | |
| | purge step | (preferably | |
| | | 0.4 to 0.8) | |
| | RF-On step | 1.0 to 5.0 | |
| | | (preferably | |
| | | 2.0 to 4.0) | |
| | Reactant | 0.5 to 4.0 | |
| | purge step | (preferably | |
| | | 1.0 to 3.0) | |
| | Treatment gas | | 1.0 to 5.0 |
| | feeding step | | (preferably |
| | | | 2.0 to 4.0) |
| | RF-On step | | 2.0 to 8.0 |
| | | | (preferably |
| | | | 3.0 to 6.0) |
| Plasma | RF power (W) | 400 to 1,000 | 100 to 500 |
| condition | | (preferably | (preferably |
| | | 500 to 800) | 200 to 400) |
| | RF frequency | 10 MHz to 60 MHz | 10 MHz to |
| | (MHz) | | 60 MHz, or |
| | | | 400 kHz to |
| | | | 600 kHz |
| Type of gas | Source gas | TDMAT | |
| | Reactant | N₂, H₂ | |
| | Treatment gas | | N₂, H₂ |
| Gas flow rate | Source carrier | 500 to 2,000 | |
| (sccm) | Ar | (preferably | |
| | | 700 to 1,500) | |
| | Purge Ar | 2,000 to 4,000 | 1,000 to 3,000 |
| | | (preferably | (preferably |
| | | 2,500 to 3,500) | 1,500 to 2,500) |
| | N₂ | 500 to 1,000 | 300 to 800 |
| | | (preferably | (preferably |
| | | 700 to 900) | 400 to 700) |
| | H₂ | 50 to 300 | 800 to 2,000 |
| | | (preferably | (preferably |
| | | 100 to 200) | 1,000 to 1,500) |

| | |
|---|---|
| Process temperature(° C.) | 150 to 300 (preferably 180 to 250) |
| Process pressure (Torr) | 0.5 to 3.0 (preferably 1.0 to 2.5) |

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and subcombinations of the various processes, systems, and configurations, and other features, functions, acts, and/or properties disclosed herein, as well as any and all equivalents thereof.

What is claimed is:

1. A method for forming a film on patterned structures of a substrate, comprising:
a step of loading a substrate onto a chamber;
a step of forming a film on the substrate;
a step of post treating the film; and
a step of unloading the substrate;
wherein the step of forming the film on the substrate comprises supplying a first gas and a second gas sequentially and alternately;
wherein the step of post treating the film comprises supplying a treatment gas to the substrate; and
wherein the second gas and the treatment gas are activated by RF power.

2. The method of claim 1, wherein the step of forming the film on the substrate further comprises supplying a third gas.

3. The method of claim 1, wherein the treatment gas comprises the second gas and the third gas.

4. The method of claim 3, wherein the flow rate of the second gas is greater than the flow rate of the third gas during the step of forming the film on the substrate.

5. The method of claim 3, wherein the flow rate of the third gas is greater than the flow rate of the second gas during the post treatment to the film.

6. The method of claim 3, wherein the first gas comprises a titanium-containing gas, the second gas comprises a nitrogen-containing gas and the third gas comprises a hydrogen-containing gas.

7. The method of claim 6, wherein the first gas comprises at least one of tetrakis(dimethylamino) titanium(IV), titanium isopropoxide, titanium tetrachloride, or a mixture thereof.

8. The method of claim 6, wherein the second gas comprises at least one of N₂, NH₃, N₂H₂, N₂H₄, or a mixture thereof.

9. The method of claim 6, wherein the third gas comprises diatomic hydrogen.

10. The method of claim 6, wherein the third gas removes carbons from the film.

11. The method of claim 1, wherein the step of forming a film and the step of post treatment to the substrate are repeated cyclically a plurality of times, and
wherein a cycle ratio of the step of forming a film to the step of post-treating the film is 10:1.

12. The method of claim 1, wherein a width between the patterned structures is less than 40 nm.

13. The method of claim 12, wherein a composition of the film is uniform from the upper portion to the lower portion of the patterned structure.

14. The method of claim 1, wherein the intensity of RF power applied to the second gas during the step of forming the film is greater than the intensity of RF power applied to the treatment gases during the step of post treating.

15. The method of claim 1, wherein the frequency of RF power applied to the second gas during the step of forming the film is the same or greater than the frequency of RF power applied to the treatment gases during the step of post treating.

16. The method of claim 15, wherein the frequency of RF power applied to the second gas and the frequency of RF power applied to the treatment gas are between 10 MHz to 60 MHz.

17. The method of claim 15, wherein the frequency of RF power applied to the treatment gas is low frequency between are between 400 kHz to 600 kHz.

18. The method of claim 1, wherein the patterned structure comprises at least one of silicon nitride, amorphous carbon and amorphous silicon, and
wherein the film formed on the patterned structure is TiN.

19. The method of claim 17, wherein the film forming method is a double patterning process,
wherein the TiN film is a spacer film.
